(19) United States
(12) Patent Application Publication
(10) Pub. No.: US 2023/0387943 A1
(43) Pub. Date: Nov. 30, 2023

(54) ELECTRICAL BALANCE N-PLEXER

(71) Applicant: Forefront RF Ltd, Cambridge (GB)

(72) Inventors: Leo Laughlin, Cambridge (GB); John Leslie Haine, Cambridge (GB)

(21) Appl. No.: 18/027,267

(22) PCT Filed: Sep. 21, 2021
(86) PCT No.: PCT/EP2021/075934

§ 371 Date: Mar. 20, 2023

(30) Foreign Application Priority Data
Sep. 21, 2020 (GB) 2014879.7

(51) Int. Cl. H04B 1/00; H04B 1/44

(52) U.S. Cl. CPC H04B 1/0057; H04B 1/44

(57) ABSTRACT

There is described a circuit for transmitting a transmit signal at a transmit frequency and receiving a receive signal at a receiver frequency, for use with a common antenna, comprising: a first signal junction having a transmit port for receiving the transmit signal, a receive port for outputting the receive signal, a third port and a fourth port, wherein the third and fourth port are for outputting a pair of common mode or differential mode transmit signals which are split from the transmit signal at the transmit port, and for receiving a pair of common mode or differential mode receive signals which are combined and provided to the receive port; a second signal junction having an antenna port for connection to an antenna, a second port and a third port, wherein the second and third port are for outputting the pair of common mode or differential mode receive signals which are split from the signal received at the antenna port, and for receiving the pair of common mode or differential mode transmit signals which are combined and provided to the antenna port; a phase inverter connected in a path of one of the pair of differential or common mode transmit or receive signals, wherein the pair of receive signals received at the receiver port are in-phase and the pair of transmit signals received at the antenna port are in-phase.

### FIELD OF THE INVENTION

The present invention is related to methods and apparatus for suppressing interference between a receive path and a transmit path in an n-plexer, such as a duplexer. The invention is particularly but not exclusively concerned with the implementation of an n-plexer in the front end of a radio frequency (RF) device, such as a mobile RF device.

### BACKGROUND TO THE INVENTION

A common feature of wireless communication equipment is the ability to transmit and receive wireless signals at the same time, known as full-duplex operation, for example using a frequency division duplex (FDD) scheme.

Simultaneously transmitting and receiving wireless signals leads to a problem wherein the relatively high-powered signal transmitted from the transmitter is coupled to the receiver where it can obscure a relatively low-powered signal which is desired to be received. The signal component at the receiver due to the devices own transmission is known as self-interference. Thus, a duplexer is typically required to suppress the self-interference at or before the receiver in order to enable successful reception in the presence of a transmission.

Filter based duplexers, such as surface acoustic wave (SAW) duplexers, are widely used to suppress self-interference in FDD systems. A duplexer in an FDD system is typically required to provide sufficient isolation of the receiver from the transmitter in both the transmit frequency band and the receive frequency band. Larger networks of filters can be used to isolate multiple receivers from multiple transmitters in an n-plexer. For example a quadruplexer can be used to connect two transmitters operating in two transmit frequency bands and two receivers operating in two receive frequency bands to a common antenna.

An electrical balance duplexer has been proposed in which isolation may be obtained between a transmit path and a receive path of a shared antenna by providing a variable impedance which is tuned to an antenna impedance value.

However problems are associated with implementations of the proposed electrical balance duplexer.

A first problem is that the impedance of an antenna typically exhibits variations. Even at a fixed frequency, if the antenna impedance varies over time then it may be difficult to provide the correct matching impedance for maintaining impedance balance with the variable impedance.

A second problem relates to providing isolation at two or more different frequencies. The impedance of an antenna varies notably with frequency, and it is difficult to provide isolation at two different frequencies because the balancing impedance of the variable impedance needs to be simultaneously controlled at those two different frequencies. Whilst an electrical balance duplexer may operate satisfactorily at one frequency band, where more than one frequency band is required difficulties may arise. In particular in a technique such as FDD, transmit and receive frequencies are separated, and therefore controlling the variable impedance for these different frequencies may be challenging.

A third problem relates to loss of power. The proposed electrical balance duplexer splits the power in a signal, and this can typically lead to a 3 dB loss in the transmit and receive paths. This can be a significant problem as this reduces the power efficiency of the transmitter and sensitivity of the receiver. Power loss may also be caused due to other mechanisms.

A fourth problem is that no filtering is provided within the proposed electrical balance duplexer. Filtering is desired in order to suppress out-of-band transmissions. Traditional standard duplexing for FDD provides filtering, and replacing a traditional standard duplexer with the proposed electrical balance duplexer removes that filtering.

It is an aim of the invention to provide an improved technique for suppressing interference between a receive path and a transmit in an n-plexer, which preferably solves one or more of the above stated problems.

### STATEMENT OF THE INVENTION

There is disclosed a circuit for transmitting a transmit signal at a transmit frequency and receiving a receive signal at a receiver frequency, for use with a common antenna, comprising: a first signal junction having a transmit port for receiving the transmit signal, a receive port for outputting the receive signal, a third port and a fourth port, wherein the third and fourth port are for outputting a pair of common mode or differential mode transmit signals which are split from the transmit signal at the transmit port, and for receiving a pair of common mode or differential mode receive signals which are combined and provided to the receive port; a second signal junction having an antenna port for connection to an antenna, a second port and a third port, wherein the second and third port are for outputting the pair of common mode or differential mode receive signals which are split from the signal received at the antenna port, and for receiving the pair of common mode or differential mode transmit signals which are combined and provided to the antenna port; a phase inverter connected in a path of one of the pair of differential or common mode transmit or receive signals, wherein the pair of receive signals received at the receiver port are in-phase and the pair of transmit signals received at the antenna port are in-phase.

The circuit may further comprise a transmit filter connected in a path of one of the pair of differential or common mode transmit signals, which may be configured to attenuate signals at the receive frequency. The phase inverter may be connected in the path of one of the pair of differential or common mode transmit signals. An attenuation frequency of the transmit filter may be variable. The impedance presented to the first signal junction by the transmit filter may be variable.

The circuit may further comprise a further transmit filter connected in a path of the other of the pair of differential or common mode transmit signals, configured to attenuate signals at the receive frequency. The phase inverter may be connected in the path of the other of the pair of differential or common mode transmit signals. An attenuation frequency of the further transmit filter may be variable. The impedance presented to the first signal junction by the further transmit filter may variable.

The circuit may further comprise a receive filter connected in a path of one of the pair of differential or common mode receiver signals, configured to attenuate signals at the transmit frequency. The phase inverter may be connected in the path of one of the pair of differential or common mode receiver signals. An attenuation frequency of the receive filter may be variable. The impedance presented to the first signal junction by the receive filter may be variable.

The circuit may further comprise a further receive filter connected in a path of the other of the pair of differential or common mode receiver signals, configured to attenuate signals at the transmit frequency. The phase inverter may be connected in the path of the other of the pair of differential or common mode receiver signals. An attenuation frequency of the further receive filter may be variable. The impedance presented to the first signal junction by the further receive filter may be variable.

One or more filters may be provided. One or more of the transmit and receive paths may be provided with a filter. One or more of the transmit and receive paths may be provided with a phase inverter. The phase inverter, where provided, may be configured to provide an inversion at a particular frequency such as the transmit or receive frequency, and not provide an inversion at another frequency, such as the other of the transmit or receive frequency.

A single filter may be provided in one of the transmit or receive paths, in combination with a phase inverter.

The circuit may further comprise: a first filter module, comprising: a first transmit filter connected in a first path of one of the pair of differential or common mode transmit signals, configured to attenuate signals at the receive frequency; and a first receiver filter connected in a second path of one of the pair of differential or common mode receiver signals, configured to attenuate signals at the transmit frequency, a second filter module comprising: a second transmit filter connected in a third path of the other of the pair of differential or common mode transmit signals, configured to attenuate signals at the receive frequency; and a second receiver filter connected in a fourth path of the other of the pair of differential or common mode transmit signals, configured to attenuate signals at the receiver frequency, wherein the phase inverter is connected in one of the first, second, third or fourth paths.

An attenuation frequency of each of the first and second transmit filters and first and second receive filters is variable. The attenuation frequencies of the first and second transmit filters correspond to a receive frequency, and the attenuation frequencies of the first and second receive filters correspond to a transmit frequency.

An impedance presented by each of the first and second filter modules to the first signal junction may be variable. The impedance presented by the first filter module to the first signal junction may be substantially equal to the impedance presented by the second filter module to the first signal junction. The impedance presented by the first and second transmit filters of the first and second filter modules to the first signal junction may be substantially equal. The impedance presented by the first and second receive filters of the first and second filter modules to the first signal junction may be substantially equal.

The impedance presented to the first signal junction by the first or second filter modules may be varied in ordered to minimise interference between the transmit port and the receive port of the first signal junction. The impedance presented to the first signal junction by each of the first and second modules may be varied such that each has a different value.

The second signal junction may have a fourth port for connection to an antenna balancing impedance. The antenna balancing impedance may be variable. The antenna balancing impedance may be varied to minimise interference between the transmit port and receive port of the first hybrid junction. The antenna balancing impedance may be varied to compensate for the antenna impedance.

The first signal junction may be a 180° hybrid junction. The second signal junction may be a 180° hybrid junction. The first signal junction may be a 90° hybrid junction with a 90° phase shifter connected at the third or fourth port. The second signal junction may be a 90° hybrid junction with a 90° phase shifter connected at the second or third port.

The first signal junction may be a rat-race coupler. The second signal junction may be a rat-race coupler. The second signal junction is a balun.

The first port of the first signal junction may be connected to a radio frequency, RF, power amplifier, and the second port of the first final junction is connected to a low noise amplifier, LNA.

The circuit is preferably an improved electrical balance circuit.

A duplexer may comprise the circuit as disclosed, being an improved electrical balance duplexer.

There is disclosed an n-plexer comprising a first plurality of radio frequency, RF, power amplifiers connected to the first port of the first signal junction, each corresponding to one of a first plurality of transmit frequencies, and a second plurality of low noise amplifiers, LNAs, connected to the second port of the first signal junction, each corresponding to a second plurality of receive frequencies, the antenna port of the second signal junction outputting signals at each of the first plurality of frequencies and receiving signals at each of the second plurality of frequencies.

There may be provided, between the third and fourth ports of the first signal junction and the second and third ports of the second signal junction, at least one transmit filter for each transmit frequency, and at least one receive filter for each receiver frequency.

There may be provided, between the third and fourth ports of the first signal junction and the second and third ports of the second signal junction, a pair of transmit filters for each transmit frequency, and pair of receive filters for each receiver frequency, each one of the pair being provided in a different path of a pair of paths corresponding to a pair of differential or common mode transmit or receive signals, for that transmit or receive frequency.

A n-plexer may comprise the circuit as disclosed, being an improved electrical balance n-plexer.

There is disclosed a multi-input, multi-output, MIMO, circuit comprising: a plurality of circuits, each having the first port of the first signal junction arranged to receive one of a plurality of transmit signals, and each having the second port of the first signal junction arranged to output one of a plurality of receive signals, and each having the first port of the second signal junctions connected to one of a plurality of antennas.

There may be provided a plurality of canceller circuits, each associated with one of the plurality of circuits as variously defined above, each canceller circuit being connected between the transmit port of one of the plurality of circuits , and the receive port of one or more of the others of the plurality of circuits.

At least two of the plurality of transmit signals may be of a same frequency. At least two of the plurality of transmit signals may be of a different frequency. At least two of the plurality of receive signals may be of a same frequency. At least two of the plurality of receive signals may be of a different frequency.

A MIMO circuit may comprise the circuit as disclosed, being an improved MIMO circuit.

There is disclosed a differential circuit for transmitting the transmit signal at the transmit frequency and receiving the receive signal at the receiver frequency, for use with a common antenna, comprising: a first circuit, for receiving at the first port of the first signal junction a first differential output of a transmit signal from a transmit amplifier, and for outputting from the second port of the first signal junction to one or both of the differential inputs of a receive amplifier; a second circuit, for receiving at a first port of the first signal junction a second differential output of the transmit signal from the power amplifier, and for outputting from the second port of the first signal junction to one or both of the differential inputs of the receive amplifier; a further signal junction having first and second ports connected to the first ports of the each of second signal junctions of the first and second circuits, and a third port connected to an antenna for transmitting the signals and receiving the receive signal.

The n-plexer differential may further comprise a first plurality of radio frequency, RF, power amplifiers having a first differential output connected to the first port of the first signal junction of the first circuit, each corresponding to one of a first plurality of transmit frequencies, and having a second differential output connected to the first port of the first signal junction of the second circuit, each corresponding to one of the first plurality of transmit frequencies, and a second plurality of low noise amplifiers, LNAs, having a first differential input connected to the second port of the first signal junction of the first circuit and/or the second port of the first signal junction of the second circuit, and having a second differential input connected to the second port of the first signal junction of the second circuit and/or the second port of the first signal junction of the second circuit, each corresponding to a second plurality of receive frequencies.

There is provided a multi-input, multi-output, MIMO, differential circuit comprising: a plurality of first circuits and second circuits, each having the first port of the first signal junction of the first and second circuits arranged to receive one of a differential pair of a plurality of transmit signals, and each having the second port of the first signal junction of the first and second circuits arranged to output one of a plurality of receive signals, and each having the first port of the second signal junctions of the first and second circuits connected to one of a plurality of antennas.

An improved n-plexer circuit or improved MIMO circuit may be implemented as a differential circuit, utilising the improved electrical balance duplexer circuit.

There is provided a filter module comprising: a first filter of a first frequency band; a second filter of a second frequency band; a phase inverter of the first frequency band, wherein signals in the first frequency band are phase inverted, and signals of the second frequency band are not phase inverted.

A first terminal of the filter module may be connected to first terminals of the first and second filters; a second terminal of the first filter may be connected to a first terminal of the phase inverter; and a second terminal of the filter module may be connected to a second terminal of the phase inverter and a second terminal of the second filter.

There may be provided a method for providing the circuitry, or any part of the circuitry. There may be provided a method for controlling any part of the circuitry. There may be provided a computer program which when executed on a processor performs any part of the method. There may be provided computer program product for storing code of such a computer program.

### BRIEF DESCRIPTION OF THE FIGURES

The invention is now described with reference to the accompanying drawings, in which:

FIG. 1 illustrates an exemplary electrical balance duplexer;

FIG. 2(a) illustrates an example of an improved electrical balance duplexer;

FIG. 2(b) illustrates an alternate example of an improved electrical balance duplexer;

FIG. 3 illustrates a modification to the improved electric balance duplexer of FIG. 2(a);

FIG. 4 illustrates an alternative improved electrical balance duplexer;

FIG. 5(a) illustrates an example implementation of a differential duplexer using an improved electrical balance duplexer;

FIG. 5(b) illustrates an alternate example implementation of a differential duplexer using an improved electrical balance duplexer;

FIG. 6 illustrates an example implementation of a system with multiple antennas using an improved electrical balance duplexer;

FIG. 7 illustrates an example implementation of a quadplexer using an improved electrical balance duplexer;

FIGS. 8(a) and 8(b) illustrate an example implementation of hybrid junctions suitable for an improved electrical balance duplexer;

FIGS. 9(a) and 9(b) illustrate an alternative example implementation of hybrid junctions suitable for an improved electrical balance duplexer; and

FIGS. 10(a) and 10(b) illustrate an alternative example implementation of hybrid junctions suitable for an improved electrical balance duplexer.

### DESCRIPTION OF PREFERRED EMBODIMENTS

The invention is now described by way of reference to examples and embodiments.

Examples are presented of a duplexer, but in general the described techniques are applicable to an n-plexer. The simplest implementation of an n-plexer is a duplexer. In general an n-plexer provides for a first plurality of transmit frequencies and a second plurality of received frequencies. The first and second plurality may be the same value or may be different values. An example of a quadplexer is described herein to illustrate how the techniques described may be extended beyond a duplexer arrangement.

An exemplary, but non-limiting, implementation of the apparatus described is in the front end of an RF device, such as a mobile RF device, such as a mobile phone.

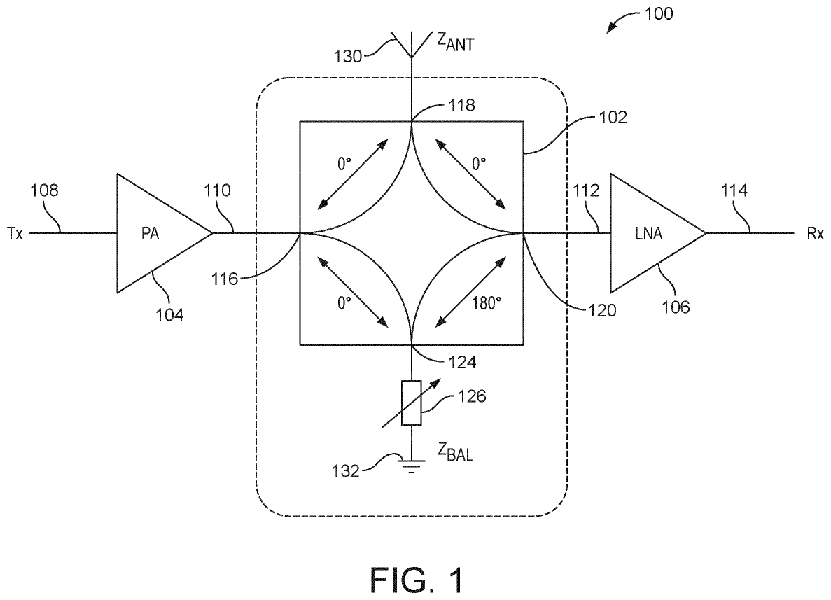

With reference to FIG. 1 there is illustrated an exemplary apparatus for transmitting and receiving signals using a single antenna, which includes an exemplary electrical balance duplexer 100. The exemplary electrical balance duplexer 100 includes a hybrid junction 102 and a variable impedance 126. It is connected to a power amplifier (PA) 104, a low noise amplifier (LNA) 106, and an antenna 130.

The power amplifier 104 receives a transmit signal (Tx) on line 108, and outputs a signal to a port 116 of the hybrid junction 102 on line 110. The LNA 106 receives a signal on line 112 from a port 120 of the hybrid junction 102, and outputs a received signal (Rx) on line 114. The variable impedance 126 is connected between a port 124 of the hybrid junction 102 and ground 132. The antenna 130 is connected to a port 118 of the hybrid junction 102.

The hybrid junction 102 connects the ports 116 and 118, 118 and 120, 116 and 124, and 120 and 124. There is 0° of phase shift between the ports 116 and 118, 118 and 120, and 116 and 124. There is 180° phase shift between the ports 120 and 124.

The antenna 130 has an antenna impedance value denoted Z_{ANT}. The variable impedance 126 has a balancing impedance value denoted Z_{BAL}. The variable impedance 126 is provided to balance the impedance of the antenna 130.

In use, a transmit signal is delivered on line 108, and applied by the power amplifier 104 to port 116 of the hybrid junction. The hybrid junction 102 delivers the transmit signal to the antenna at port 118, and to the balancing impedance at port 124. A received signal is received by the antenna 130 and delivered to the hybrid junction at port 118. The LNA 106 receives the receive signal on line 112 from the antenna 130 and the balancing impedance 126 via ports 118 and 124.

A hybrid junction may in general be a four-port lossless reciprocal network in which opposite pairs of ports are isolated from each other. Assuming all ports are terminated with the correctly matched characteristic impedance, a signal arriving at any one of the hybrid junction's ports is divided between two adjacent ports, but not coupled to the opposite port. This property of electrical balance can be exploited to isolate a transmitter and receiver circuitry, and allow use of a shared antenna.

As shown in FIG. 1, a transmit signal received at port 116 is divided between ports 118 and 124 and isolated from port 120. A receive signal arriving at port 118 is divided between ports 116 and 120, and isolated from port 124.

In the case of an electrical balance duplexer using an ideal 180° hybrid junction, the transmit-to-receive isolation is maximized (theoretically infinite) when the variable impedance is equal to the impedance of the antenna. In an ideal implementation, all power received or incident at the transmit port 116 is divided between the antenna port 118 and the balance port 124. The low noise amplifier 106 is then isolated, and there is no leakage as long as balance is maintained. Similarly all power incident at the received port 120 is divided between the antenna port 118 and the balance port 124.

There are various problems associated with implementing the apparatus of FIG. 1 as a duplexer.

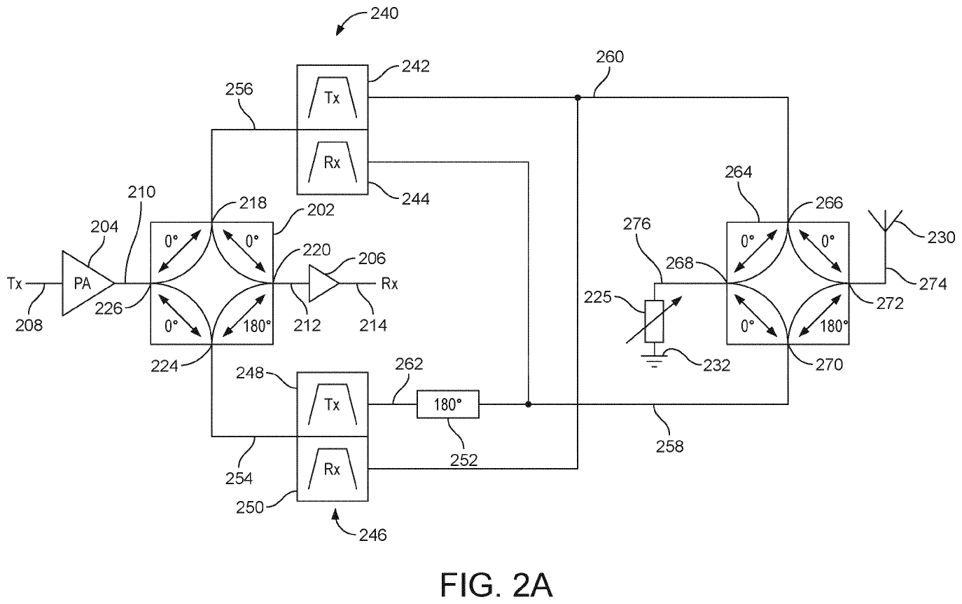

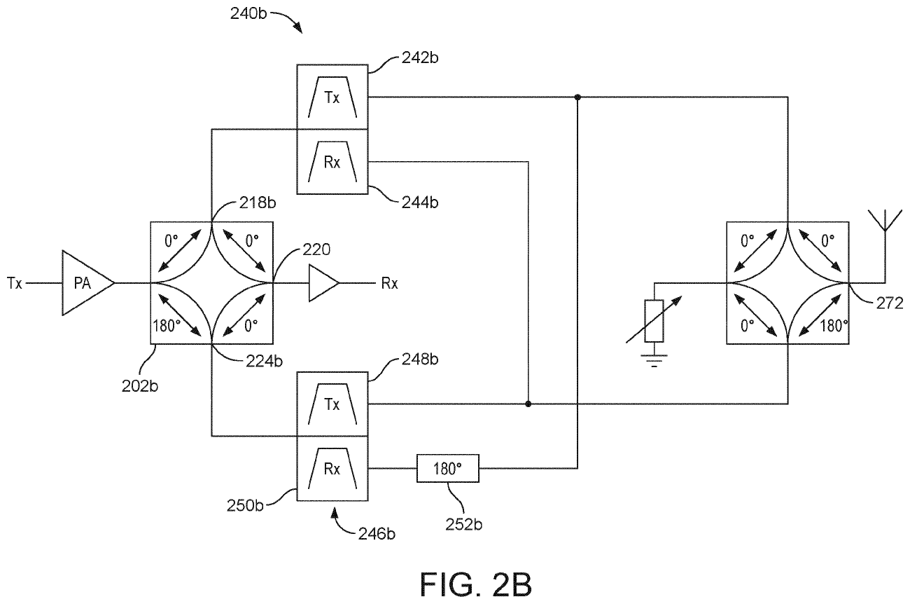

With reference to FIG. 2(a) there is illustrated an exemplary implementation of an improved apparatus for transmitting and receiving signals and suppressing interference between the transmit path and the receive path in a duplexer.

The exemplary implementation of the improved apparatus 200 comprises a first hybrid junction 202, a second hybrid junction 264, a first filter module 240, a second filter module 246, a phase shifter module 252, and a variable impedance 225. The apparatus 200 is connected to a power amplifier (PA) 204, a low noise amplifier (LNA) 206, and an antenna 230.

The apparatus 200 of FIG. 2(a) may be termed an improved electrical balance duplexer, which is connected to the power amplifier, the low noise amplifier, and the antenna.

A transmit signal Tx is received on line 208 at the input to the PA 204, and provided by the PA on line 210 to a transmit port 226 of the first hybrid junction 202. A port 218 of the first hybrid junction is connected via line 256 to the filter module 240, and a port 224 of the first hybrid junction 202 is connected by line 254 to the filter module 246. A receive port 220 of the first hybrid junction 202 is connected on line 212 to the input of the LNA 206, which generates at its output on line 214 the receive signal Rx.

The filter module 240 includes a transmit filter 242 and a receive filter 244. The transmit filter 242 is connected between line 256 and a line 260. The receive filter 244 is connected between line 256 and a line 258.

The filter module 246 includes a transmit filter 248 and a receive filter 250. The transmit filter 248 is connected between line 254 and a line 262. The receive filter 250 is connected between line 254 and the line 260.

The line 262 connected to the transmit filter 248 is connected to one terminal of the phase shifter 252, and a second terminal of the phase shifter 252 is connected to the line 258.

The line 260 is connected to a port 266 of the second hybrid junction 264, and the line 258 is connected to a port 270 of the second hybrid junction 264.

The variable impedance 226 is connected between a balance port 268 of the second hybrid junction 264 and ground 232. A line 276 connects the variable impedance 226 to the balance port 268.

The antenna 230 is connected via a line 274 to an antenna port 272 of the second hybrid junction 264.

In the first hybrid junction 202, the ports 226 and 218 are connected with 0° phase shift, the ports 218 and 220 are connected with 0° phase shift, the ports 226 and 224 are connected with 0° phase shift, and the ports 220 and 224 are connected with 180° phase shift.

In the second hybrid junction 264, the ports 266 and 268 are connected with 0° phase shift, the ports 268 and 270 are connected with 0° phase shift, the ports 266 and 272 are connected with 0° phase shift, and the ports 270 and 272 are connected with 180° phase shift.

The transmit signals are routed from the power amplifier 204 to the antenna 206. A first transmit path is from the power amplifier 204 via ports 226 and 218 of the first hybrid junction, through filter 242, and ports 266 and 272 of the second hybrid junction 264. A second path for the transmit signal from the power amplifier 204 is provided via ports 226 and 224 of the first hybrid junction, through filter 248, through phase shifter 252, and through ports 270 and 272 of the second hybrid junction.

Receive signals are routed from the antenna 230 to the low noise amplifier 206. A first receive path is from the ports 272 and 266 of the second hybrid junction 264, through the receive filter 250, and through the ports 224 and 220 of the first hybrid junction. A second receive path is through the ports 272 and 270 of the second hybrid junction 264, through the receive filter 244, and through the ports 218 and 220 of the first hybrid junction.

The details of the exemplary apparatus of FIG. 2(a) will now be described.

The preferable provision of the filter modules 240 and 246 enables the exemplary improved electrical balance duplexer of FIG. 2(a) to operate as a duplexer.

This filtering may not only enable duplexing or multiplexing, but also may serve to attenuate unwanted out-of-band components in the transmit and receive signals, addressing one of the problems of electrical balance duplexers mentioned above.

The filtering provided by the filter modules 240 and 246 allows selective application of filtering at the transmit frequency and the receive frequency. That is the transmit filters and the receive filters operate at different frequencies.

It can be understood from FIG. 2(a) and the foregoing discussion that the transmit signals are routed through the transmit filters 242 and 248, and the receive signals are routed through the receive filters 244 and 250.

Operation of the exemplary improved electrical balance duplexer preferably requires transmitter-receiver isolation, i.e. isolation between ports 226 and 220. This isolation may depend, at least in part, on an embodiment in which the impedances of the filter circuits within each filter module 240 and 246 are matched. This may be impedance matching (i.e. impedance equality) between the pair of filters 242 and 244, and impedance matching (i.e. impedance equality) between the pair of filters 248 and 250, or otherwise, impedance matching between the impedance seen at the input of the filter module 240 and the impedance seen at the input of the filter module 246. In each case the impedances in question are those impedances presented by the filters 242 and 244 of filter module 240 to the hybrid junction at port 218, and the impedance presented by the filters 248 and 250 of the filter module 246 to the hybrid junction at port 224.

In this arrangement the transmit-receive isolation depends on the matching of the impedances, and not on the stop band rejection of the filters. Thus lower specification filters can be used than would otherwise be needed, which are easier to implement.

In one embodiment matching, or substantial matching, between filter impedances may be achieved by using identically designed pairs of filters, e.g., the filter pair in filter module 240 may be of identical design to the filter pair in filter module 246. However, in other embodiments, the filter pairs in filter modules 240 and 246 may differ from one-another in design and/or implementation, but in such a case transmit-receive isolation may still be achieved in the band or bands of interest by ensuring that the impedances presented to the hybrid junction at ports 218 and 224 are equal or close to equal over the frequency band or bands of interest, inasmuch as circuits with differing designs may still exhibit the same or similar impedances over particular frequency ranges.

Poor selectivity in the filters increases insertion losses due to reduced selectivity of signal routing. For example some of the receive energy may end up in the transmitter. However this does not affect transmit-receive isolation, which depends on the relationship between the impedances presented to the hybrid junction at ports 218 and 224.

The behaviour of the exemplary embodiment in FIG. 2(a) can be described mathematically as follows using an admittance matrix description. Defining variables T and T′ to represent the 2-port admittance matrices of the transmit filters 242 and 248 respectively, and variables R and R′ to represent the 2-port admittance matrices of the receive filters 244 and 250 respectively, it is possible using basic circuit theory and admittance matrix manipulation, to define the 4-port admittance matrix of the example embodiment shown in FIG. 2(a) as:

$$( \begin{matrix}{i}_{5} \\ {i}_{6} \\ {i}_{7} \\ {i}_{8}\end{matrix} ) = ( \begin{matrix}{S}_{1} + {S}_{2} & {S}_{1} - {S}_{2} & {Y}_{57} & {Y}_{58} \\ {S}_{1} - {S}_{2} & {S}_{1} + {S}_{2} & {Y}_{67} & {Y}_{68} \\ {Y}_{75} & {Y}_{76} & ( {S}_{3} + {S}_{4} ) & ( {S}_{3} - {S}_{4} ) \\ {Y}_{85} & {Y}_{86} & ( {S}_{3} - {S}_{4} ) & ( {S}_{3} + {S}_{4} )\end{matrix} ) ( \begin{matrix}{v}_{5} \\ {v}_{6} \\ {v}_{7} \\ {v}_{8}\end{matrix} ) \qquad Equation 1$$

where

S₁=T₁₁+T₁₂+R₁₁+R₁₂;

S₂=T′₁₁+T′₁₂+R′₁₁+R′₁₂;

S₃=T₂₂+T₁₂+R′22+R′¹²;

S₄=T′₂₂+T′₁₂+R22+R¹²;

Y₇₅=Y₅₇=−(T₁₂+R′₁₂+R₁₂−T′₁₂)

Y₇₆=Y₆₇=−(T₁₂−R′₁₂+R₁₂+T′₁₂)

Y₈₅=Y₅₈=−(T₁₂+R′₁₂−R₁₂+T′₁₂)

Y₈₆=Y₆₈=−(T₁₂−R′₁₂−R₁₂−T′₁₂)

and where v₅, v₆, v₇, and vs are the voltages and i₅, i₆, i₇, and i₈ are the currents, at ports 5, 6, 7, and 8, respectively, and where port 5 corresponds to the transmit port 226, port 6 corresponds to the receive port 220, port 7 corresponds to the balance port 260, and port 8 corresponds to the antenna port 272, and where normal matrix index notation is used to index the 2×2 filter matrices (e.g. T₂₁ is the transfer admittance from port 1 to 2 of the 2-port network described by admittance matrix T).

Observing the 4-port admittance matrix describing the example embodiment in FIG. 2(a), it may be noted that the transfer admittance between port 5 (the transmitter) and 6 (the receiver) is given by S₁-S₂. Mathematically, transmit-to-receive isolation is achieved when the condition (S₁−S₂=0) is satisfied. In the case where T=T′ and R=R′, i.e., the two transmit filters have identical admittance matrices, and the two receive filters have identical admittance matrices, as may have been achieved by tuning these circuits (as described below), then it may be noted that S₁=S₂ and there is therefore zero transmission admittance between port 5 and 6, i.e. between the transmitter and receiver. It is sufficient that the input admittance parameters of the filters are equal, i.e. T₁₁=T′₁₁, T₁₂=T′₁₂, R₁₁=R′₁₁, R₁₂=R′₁₂, to satisfy (S₁−S₂=0).

Thus isolation may be achieved when the impedance presented in the filters is equal, assuming the hybrid circuit is ideal.

One or more of the filters 242, 244, 248 and 250 may have a frequency response which is tuneable or otherwise reconfigurable. This could be, for example, to allow one or more of the filters to be tuned to a particular operating frequency band as may be desired. This could also allow the bandwidth of one or more of the filters to be configured as desired. Thus, tuning of one or more of these filters can enable a particular FDD operating band to be selected for operation.

Tuning of any or all of these filters may be achieved through various means. In one embodiment, individual components within one or more of the filters 242, 244, 248 and 250 may be designed to be tuneable or otherwise variable, with the tuning of one or more components within a filter having the effect of tuning the overall response of a filter network. Such tuning of components may be in continuous or discrete steps. In another embodiment, one or more of the filters 242, 244, 248 and 250 may include switches and numerous additional components which can selectively be included or excluded from the network by opening or closing said switches, thereby having the impact of reconfiguring the overall response of one or more of the filters 242, 244, 248 and 250.

Tuning or otherwise reconfiguring one or more of the filters 242, 244, 248 and 250 may be achieved using tuning control inputs to one or more of the filters 242, 244, 248 and 250. To configure the system for operation in a particular desired band or bands, or otherwise tuning a filter to have a desired filter characteristic, requires the correct tuning settings to be determined and applied to the tuning control inputs. Tuning settings may be applied to the tuning control inputs by means of a tuning control circuit, which may, for example, be a microprocessor and associated peripheral logic or circuitry arranged to present digital or analogue control signals to the tuning control inputs.

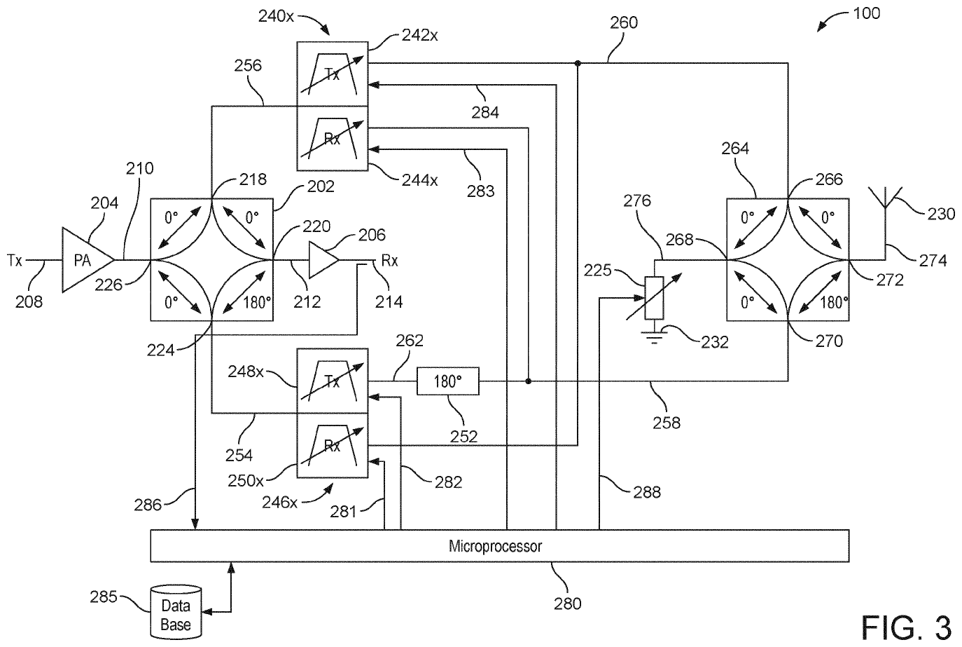

With reference to FIG. 3 there is illustrated a modification to the apparatus of FIG. 2(a) to allow for tuning of the filters to an operating band or bandwidth. Like reference numerals from FIG. 2 (a) are used in FIG. 3 to denote like elements.

As shown in FIG. 3 there is additionally provided a microprocessor 280. The filter module 240 providing filters 242,244 is replaced by a filter module 240x providing variable filters 242x,244x. The filter module 246 is replaced by a filter module 246x providing variable filters 248x,250x.

The microprocessor 280 provides control signals 281,282,283,284 to the respective filters 242x,244x,248x,250x to control the setting of respective filter variables. This control allows the frequency and bandwidth of each of these filters to be controlled.

In one embodiment, determining the required control settings could be achieved, for example, by selecting a set of tuning settings from a database 285 (or other memory or storage device) to which the microprocessor 280 is connected, which database stores control settings. A database of tuning settings could, for example, relate a choice of frequency band or bands, to a set of tuning settings which when applied to one or more of the tuning control inputs 281,282,283,284 will result in one or more of the filters 242x, 244x, 248x and 250x being tuned to the chosen frequency band or bands. The database of tuning settings could, for example, be known or calculated from circuit design parameters of the filters 242x, 244x, 248x and 250x.

Additionally, tuning settings for a particular frequency band or bands may also be known or calculated from the circuit design parameters, and the expected impedance of the antenna and hybrid junction, in a given band or bands, to which the filters are connected. In this way the tuning settings can provide an improved match with the antenna in a given band or bands, which may be beneficial to compensate for an antenna impedance which can vary with frequency.

In certain embodiments, selecting and applying tuning settings from a database of tuning settings may only result in approximate tuning of the filters. This could, for example, have the desired effect of selecting the required frequency band or bands, but result in insufficient transmit-receive isolation, as the impedances of the filter modules 240 and 246 presented to the hybrid junction at ports 218 and 224 may not match or be otherwise valued as is required to obtain the required level of transmit-to-receive isolation.

Thus, in certain embodiments, it may be beneficial for one or more of the filters 242, 244, 248 and 250 to be further tuned for the purpose of increasing transmit-to-receive isolation. This could be achieved, for example, by measuring or otherwise inferring the power of the self-interference arriving at the receiver in one or more frequency band, which may include transmit frequency bands and/or receive frequency bands, and making adjustments to the tuning settings applied to the tuning control inputs of one or more of the filters 242, 244, 248 and 250 in order to decrease the power of the self-interference signal.

Such a fine tuning process could, for example, be implemented on a microprocessor 280 of FIG. 3, which processes one or more receive signal and/or one or more other inputs from which self-interference power can be inferred in one or more frequency bands.

In FIG. 3 there is shown an input 86 to the microprocessor 280 from the receive line 214, which may provide a measurement of power of the received signal. The microprocessor 280 may perform an isolation tuning process which iteratively makes adjustments to the tuning settings for the purpose of decreasing self-interference power. In this way the isolation tuning process may increase the transmit-to-receive isolation.

As discussed above in one embodiment where the hybrid junction 202 is an ideal 180° hybrid junction, self-interference will be eliminated when the impedances of the filter modules 240 and 246 presented to the hybrid junction at ports 218 and 224 are equal. Therefore in this case the isolation tuning process will converge towards tuning settings which result in equal impedances being presented by the filters to the hybrid junction at ports 218 and 224.

The above discussion assumes an ideal hybrid junction, and adjusting the impedance settings of the filters and/or the frequency settings of the filters assuming an ideal hybrid system.

In another embodiment, one or more of the hybrid junctions 202 and 264 may exhibit some imperfections, such as, for example, in the case of hybrid junction 202 a direct coupling path between port 226 and port 220 of the hybrid junction, and/or imperfect amplitude and/or phase relationships between the ports as compared to an ideal hybrid junction. Such imperfections in one or more of the hybrid junctions may have the effect that equal impedances presented to the hybrid junction at ports 218 and 224 will not result in adequate transmit-to-receive isolation. In such a case, a filter tuning process may have the effect of compensating for the imperfections of the hybrid junction, as the filter tuning algorithm may converge towards the filter tuning settings which maximise isolation, and thereby set the impedances presented to the hybrid junction at ports 218 and 224 to whatever values are necessary to provide sufficient transmit-receive isolation in one or more frequency bands.

Use of an isolation tuning process thus may enable an implementation to utilize a lower quality and/or cheaper hybrid junction.

This isolation tuning process may be performed by the microprocessor 280, controlling the settings on lines 281,282,283,284. The microprocessor 280 may use the feedback on line 286 to determine the level of isolation achieved.

In certain embodiments, an isolation tuning process may compensate for imperfections in the implementation of the tuning of one or more of the filters 242, 244, 248 and 250 and the associated tuning control circuitry. Such imperfections may have the effect that the relationship between the tuning control settings and the resulting impedances of one or more of the filters 242, 244, 248 and 250, differs in implementation compared to the design. However, the isolation tuning process may converge towards the tuning settings which maximise isolation regardless of the relationship between the tuning control settings and the resulting impedances of one or more of the filters 242, 244, 248 and 250.

In certain embodiments, the isolation tuning process may operate only on one transmit filter (either 242a or 248a in FIG. 3) and/or only one receive filter (either 244a or 250a in FIG. 3), with in each case the other having it's tuning control settings unchanged by the isolation tuning process. This may be beneficial to ensure the frequency band or bands that are selected for operation remain selected for operation.

In an ideal implementation, the antenna 230 will be perfectly impedance matched to the preceding circuits, and the variable impedance 225 can be controlled to match the impedance of the antenna.

However, in a practical implementation, the antenna 230 may not be perfectly impedance matched to the preceding circuits. Where there exists an impedance mismatch between the antenna and the circuits to which the antenna is connected at port 272, a portion of the transmit signal Tx amplified by the power amplifier 204 and delivered to the antenna 230 may be reflected due to said impedance mismatch. This may result in a transmit signal reflection entering the hybrid junction 264 at port 272. The transmit signal reflection may comprise signal components in one or more frequency bands, which may include a transmit and receive frequency bands.

A transmit signal reflection may have the unwanted effect of being coupled to the low noise amplifier 206. This may result in self-interference which may impact on the reception of the desired receive signal which has been received in one or more frequency bands.

The variable impedance 225 is provided to cancel the transmit signal reflection from the antenna 230. In the exemplary embodiment shown in FIG. 2(a), setting the variable impedance 225 to be mismatched with the preceding circuitry will result in another transmit signal reflection entering the hybrid junction at port 268 which cancels with the transmit signal reflection entering the hybrid junction at port 272. This impedance 226 may adaptively track the antenna impedance variation in order to maintain isolation.

In the exemplary embodiment shown in FIG. 2(a), if the impedances connected to ports 268 and 272 of the hybrid junction 264 are both correctly matched to the preceding circuits, there would ideally be no coupling between ports 266 and port 270, owing to the isolating property of the hybrid junction 264. However, a transmit signal reflection entering the hybrid junction 264 at port 272 may result in the transmit signals being coupled between ports 266 and port 270 (in both directions).

Where signals are coupled between ports 266 and 270 of the hybrid junction 264 this, together with the limited stopband rejection of the filters used in a practical implementation, introduces further signal coupling mechanisms which can result in self-interference at the receiver.

In the exemplary embodiment shown in FIG. 2(a) it may be observed, for example, that a transmit signal component is coupled through the filter 248 and phase shifter 252 and enters the hybrid junction 264 at port 270. A transmit signal reflection at port 272 may result in transmit signal energy being coupled to port 266 and exiting the hybrid junction via line 260. This energy may be coupled through to the receive filter 250 to the hybrid junction 202, through which it may be coupled to the low noise amplifier 206 where it is received as self-interference. Likewise, transmit signal energy may be coupled through the receiver filter 250 and enter the hybrid junction 264 at port 266. A transmit signal reflection at port 272 may result in transmit signal energy being coupled to port 270 and exiting the hybrid junction via line 258. This energy may be coupled through to the phase shifter 252 and filter 248 to the hybrid junction 202, through which it may be coupled to the low noise amplifier 206 where it is received as self-interference. The transmit signal reflection may also result in corresponding self-interference coupling mechanisms involving the filters 242 and 244. Thus, a transmit signal reflection due to a mismatched antenna can result in self-interference at the receiver.

A preferable feature of the improved electrical balance circuit is thus that the transmit-receive isolation does not depend on the selectivity of the filters, and thus in certain embodiments, the selectivity of the filters 242, 244, 248 and 250 may be poor. The signal coupling mechanisms above involve signals being coupled serially through filters which may be tuned to different frequency bands, for example through the filter 248 which may be tuned to a transmit frequency band, and then via the hybrid junction 264 to filter 250 which may tuned to a receive frequency band. Although in certain embodiments the passbands of filters 248 and 250 may not overlap, the poor selectivity of the filters means that significant signal coupling may still occur, with self-interference signals leaking through the stopbands of the filters. Likewise the same may be true for corresponding self-interference coupling mechanisms involving filters 242 and 244.

Moreover, it may also be observed that the relative phase relationships in these self-interference coupling mechanisms, as determined by the phase shifter 252 and the hybrid junction 202, mean that self-interference coupled in the manner described involving filters 248 and 250, will not cancel with self-interference coupled via the corresponding self-interference coupling mechanism involving filters 242 and 244, even in the case where filter modules 240 and 246 exhibit identical responses.

Thus it may be preferable to mitigate these self-interference coupling mechanisms. This can be achieved by adjusting the tuneable impedance 225. Where the hybrid junction 264 is ideal, setting the variable impedance 225 to be equal to the antenna impedance will result in port 266 and port 270 being perfectly isolated from one another, which prevents self-interference being coupled through the self-interference coupling mechanisms described above. This isolation occurs because a signal entering the hybrid junction 264 at port 270 and being reflected at port 272 does not exit the hybrid junction 264 at port 266 because it is cancelled by an equal reflection occurring at port 268. Likewise, a signal entering the hybrid junction 264 at port 266 and being reflected at port 272 does not exit the hybrid at port 270 because it is cancelled by an equal reflection occurring at port 268. It is notable that the cancellation occurring within the hybrid junction 264 may comprise the cancellation of a multitude of self-interference coupling mechanisms which involve coupling between port 266 and port 270 in both directions.

In certain embodiments the hybrid junction 264 may not be ideal and may exhibit one or more imperfections, for example amplitude imbalance, phase imbalance, or direct leakage of signals between opposite (isolated) ports. In such an embodiment, isolation can still be achieved between port 266 and port 270, however the value of the variable impedance which results in isolation between port 266 and port 270 may not be equal to the antenna impedance. In such an embodiment, the variable impedance can be adjusted to whatever value is required to isolate ports 266 and port 270 from one-another. In all cases the isolation between ports 266 and port 270 will be reciprocal because the hybrid junction is a reciprocal network.

As shown in FIG. 3 the microprocessor outputs a control signal; 288 to the variable impedance 225 to control the impedance value.

Mathematically, the dependence of the transmit to receive isolation on the matching of the antenna and balancing impedances can be described as follows. In the case where T=T′ and R=R′ (i.e. the two transmit filters 242 and 248 are identical, and the two receive filters 244 and 250 are identical), Equation 1 can be simplified as:

$$( \begin{matrix}{i}_{5} \\ {i}_{6} \\ {i}_{7} \\ {i}_{8}\end{matrix} ) = 2 ( \begin{matrix}{S}_{1} & 0 & - {R}_{12} & - {T}_{12} \\ 0 & {S}_{1} & - {T}_{12} & {R}_{12} \\ - {R}_{12} & - {T}_{12} & {S}_{3} & 0 \\ - {T}_{12} & {R}_{12} & 0 & {S}_{3}\end{matrix} ) ( \begin{matrix}{v}_{5} \\ {v}_{6} \\ {v}_{7} \\ {v}_{8}\end{matrix} )$$

With admittance Y_{b} connected from to port 7 to ground representing the variable impedance 226 and admittance Yₐ connected from port 8 to ground representing the antenna 230, the voltages v₇ and v₈ can be rewritten in terms of current and admittance such that

$$( \begin{matrix}{i}_{5} \\ {i}_{6} \\ {i}_{7} \\ {i}_{8}\end{matrix} ) = 2 ( \begin{matrix}{S}_{1} & 0 & - {R}_{12} & - {T}_{12} \\ 0 & {S}_{1} & - {T}_{12} & {R}_{12} \\ - {R}_{12} & - {T}_{12} & {S}_{3} & 0 \\ - {T}_{12} & {R}_{12} & 0 & {S}_{3}\end{matrix} ) ( \begin{matrix}{v}_{5} \\ {v}_{6} \\ - {i}_{7} / {Y}_{b} \\ - {i}_{8} / {Y}_{a}\end{matrix} )$$

This matrix equation can be split such that:

$$( \begin{matrix}{i}_{5} \\ {i}_{6}\end{matrix} ) = ( \begin{matrix}{S}_{1} & 0 \\ 0 & {S}_{1}\end{matrix} ) ( \begin{matrix}{v}_{5} \\ {v}_{6}\end{matrix} ) + ( \begin{matrix}- {R}_{12} & - {T}_{12} \\ - {T}_{12} & {R}_{12}\end{matrix} ) ( \begin{matrix}- {i}_{7} / {Y}_{b} \\ - {i}_{8} / {Y}_{a}\end{matrix} ) \qquad Equation 2$$

$$( \begin{matrix}{i}_{7} \\ {i}_{8}\end{matrix} ) = ( \begin{matrix}- {R}_{12} & - {T}_{12} \\ - {T}_{12} & {R}_{12}\end{matrix} ) ( \begin{matrix}{v}_{5} \\ {v}_{6}\end{matrix} ) + ( \begin{matrix}{S}_{3} & 0 \\ 0 & {S}_{3}\end{matrix} ) ( \begin{matrix}- {i}_{7} / {Y}_{b} \\ - {i}_{8} / {Y}_{a}\end{matrix} )$$

This can be re-arranged to find i₇ and i₈ in terms of v₅, v₆, and the various admittances, giving:

$${i}_{7} = \frac{- {R}_{12} {v}_{5} - {T}_{12} {v}_{6}}{( 1 + \frac{{S}_{3}}{{Y}_{b}} )}$$

$${i}_{8} = \frac{- {T}_{12} {v}_{5} + {R}_{12} {v}_{6}}{( 1 + \frac{{S}_{3}}{{Y}_{a}} )}$$

These can be substituted into equation 2:

$$( \begin{matrix}{i}_{5} \\ {i}_{6}\end{matrix} ) = ( \begin{matrix}{S}_{l} & 0 \\ 0 & {S}_{1}\end{matrix} ) ( \begin{matrix}{v}_{5} \\ {v}_{6}\end{matrix} ) + ( \begin{matrix}- {R}_{12} & - {T}_{12} \\ - {T}_{12} & {R}_{12}\end{matrix} ) ( \begin{matrix}- \frac{- {R}_{12} {v}_{5} - {T}_{12} {v}_{6}}{{Y}_{b} ( 1 + \frac{{S}_{3}}{{Y}_{b}} )} \\ - \frac{- {T}_{12} {v}_{5} + {R}_{12} {v}_{6}}{{Y}_{a} ( 1 + \frac{{S}_{3}}{{Y}_{a}} )}\end{matrix} )$$

Expanding, rearranging, and simplifying, this yields a 2-port Y-matrix description of the example embodiment in FIG. 2(a) (assuming T=T′ and R=R′), with the two port being the transmit and receive port, as

$$( \begin{matrix}{i}_{5} \\ {i}_{6}\end{matrix} ) = ( \begin{matrix}{S}_{1} - \frac{{R}_{12}^{2}}{( {Y}_{b} + {S}_{3} )} - \frac{{T}_{12}^{2}}{( {Y}_{a} + {S}_{3} )} & \frac{{R}_{12} {T}_{12}}{( {Y}_{a} + {S}_{3} )} - \frac{{R}_{12} {T}_{12}}{( {Y}_{b} + {S}_{3} )} \\ \frac{{R}_{12} {T}_{12}}{( {Y}_{a} + {S}_{3} )} - \frac{{R}_{12} {T}_{12}}{( {Y}_{b} + {S}_{3} )} & {S}_{1} - \frac{{T}_{12}^{2}}{( {Y}_{b} + {S}_{3} )} - \frac{{R}_{12}^{2}}{( {Y}_{a} + {S}_{3} )}\end{matrix} ) ( \begin{matrix}{v}_{5} \\ {v}_{6}\end{matrix} )$$

It is notable here that the transfer admittance between transmit and receiver may be non-zero and depends (among other things) on the admittances of the antenna 230 and variable impedance 226. The transfer admittance between port 5 and 6 (and vice-versa) is:

$$\frac{{R}_{12} {T}_{12}}{( {Y}_{a} + {S}_{3} )} - \frac{{R}_{12} {T}_{12}}{( {Y}_{b} + {S}_{3} )}$$

It can be noted here that in the special case where Y_{b}=Yₐ, this expression sums to zero, resulting in theoretically infinite isolation. The condition Y_{b=}Yₐ could be satisfied in practice by tuning the variable impedance to equal the antenna impedance, thereby cancelling one or more transmit signal reflections.

Various implementations of the variable impedance 225 are possible. In one embodiment, the variable impedance may comprise a network of variable or otherwise reconfigurable components, for example resistors, capacitors, and/or inductors, or combinations thereof. Components within the variable impedance network may be designed to be tuneable or otherwise variable, with the tuning of one or more components within the network under the control of the microprocessor 280 having the effect of tuning the impedance of the overall network. Such tuning of components may be in continuous or discrete steps.

In another embodiment the variable impedance network may include switches and numerous additional components which can selectively be included or excluded from the network by opening or closing said switches, thereby having the impact of reconfiguring the impedance of the overall circuit. In one embodiment, the variable impedance may be designed to facilitate control of the impedance at a single frequency point.

In another embodiment, the variable impedance network may be designed such that impedance can be controlled simultaneously at multiple frequency points, or across a frequency band, or simultaneously across multiple frequency bands for example one or more transmit or receive frequency bands.

In certain embodiments, the variable impedance may be controlled by means of one or more impedance control inputs. The desired outcome of adjusting the variable impedance is to reduce or minimise self-interference power at the receiver. Determining the impedance control settings which reduce or minimise self-interference power could be achieved, for example, by measuring or otherwise inferring the power of the self-interference arriving at the receiver in one or more frequency bands, which may include transmit frequency bands and/or receive frequency bands, and making adjustments to the impedance control settings applied to the impedance control inputs of the variable impedance 226 in order to decrease the power of the self-interference signal. Such an impedance tuning process could, for example, be implemented on a microprocessor which processes one or more receive signal and/or one or more other inputs from which self-interference power can be inferred in one or more frequency bands, and runs an impedance tuning process which iteratively makes adjustments to the impedance control settings for the purpose of decreasing self-interference power. In this way the impedance tuning process may increase the transmit-to-receive isolation.

In some embodiments, the antenna impedance may vary over time, for example, due to electromagnetic interaction with objects in the local environment. A change in the effective antenna impedance due to interaction with the local environment would result in a change of the effective reflection coefficient at the antenna port, and thus a change in the transmit signal reflection at port 272. This may require a corresponding adjustment to the variable impedance 226 in order to maintain a particular level of transmit-to-receive isolation. Thus, in some embodiments where the antenna impedance is varying over time, it may be preferable for the impedance tuning process to be running continuously or periodically in order to maintain transmit-to-receive isolation.

The phase shifting module 252 is provided in order to provide an inversion at the transmit frequency only in the filter module 246. Because of the need to provide an inversion to the transmit signal, but not the receive signal, the receive signals are routed differently to the transmit signals.

The phase shifting required, and whether any phase shifting is required, will depend on the implementation. The provision of the phase shifting module 252 in the example balance frequency duplexer 200 is related to the specific implementation of the first hybrid junction 202 and the second hybrid junction 266. The phase shifting provided by the phase shifter module 252 may be implemented in an alternative way. The 180° phase shift provided by the phase shifter module 252 in the transmit path could alternatively be implemented in the receive path. The implementation of phase shifting may also be different in dependence upon where the phase shifting is implemented in either the first hybrid junction or the second hybrid junction, or both the first hybrid junction and the second hybrid junction.

In the arrangement as shown in FIG. 2(a), there is a requirement for the received signal to arrive at the ports of the first hybrid junction (ports 218 and 224) as a differential signal, in order for it to be routed to the low noise amplifier 206. If the received signal received at ports 218 and 224 was in phase, it would be routed towards the transmit port 226. Similarly the transmit signals must be received as a differential signal at the second hybrid junction 264, i.e. at ports 266 and 270, in order to be routed toward the antenna port 272, rather than the balance port 268.

It should be noted that the phase shifting required in either the transmit or the receive path may be different, independent of the phase shift provided between ports of either the first hybrid junction or the second hybrid junction. The implementation of the phase shift as shown in the exemplary implementation of FIG. 2(a) is based on a phase shift of 180° between ports 220 and 224 of the first hybrid junction, and a phase shift of 180° between ports 272 and 270 of the second hybrid junction 264.

In general, the signals arriving at the port 272 via the two transmit paths (at the transmit frequency) should be in-phase, and the signals arriving at the port 220 via the receive paths (at the receive frequency) should be in-phase, and phase-shifting may be implemented as appropriate in any path to ensure such in-phase signals are received at these ports.

It can also be noted that the location of the phase shift in the path may vary, and the location of phase shift 252 is exemplary.

To illustrate this, FIG. 2(b) demonstrates a further exemplary arrangement with a different phase configuration. FIG. 2(b) corresponds to FIG. 2(a), and like reference numerals are used to denote like components and connections.

In the exemplary arrangement of FIG. 2(b), the first hybrid junction 202 of FIG. 2(a) is replaced with the hybrid junction 202b. The phase shifting in the first hybrid junction 202b is different to that of the hybrid junction 202 as shown in FIG. 2(a). In the exemplary arrangement of FIG. 2(b), the transmit signals are output from the hybrid junction 202b in differential mode across ports 218b and 224b (corresponding to ports 218 and 224 of FIG. 2(a)), rather than common mode. As such, no phase shift is required in either of the transmit paths in order for the transmit signal to appear in phase at the antenna port 272.

However, again due to the different phase configuration in the first hybrid junction 202b, in order for the receive signals to combine in phase at port 220, these signals must appear in common mode at ports 218b and 224b, therefore requiring the phase shifter 252b to be present in the receive path of the receive filter 250b. Filter modules 240b and 250b correspond to filter modules 240 and 250 of FIG. 2(a), and filter 242b, 244b, 248b, 250b correspond to filters to filter modules 240 and 250 of FIG. 2(a), and filter 242, 244, 248, 250 of FIG. 2(a).

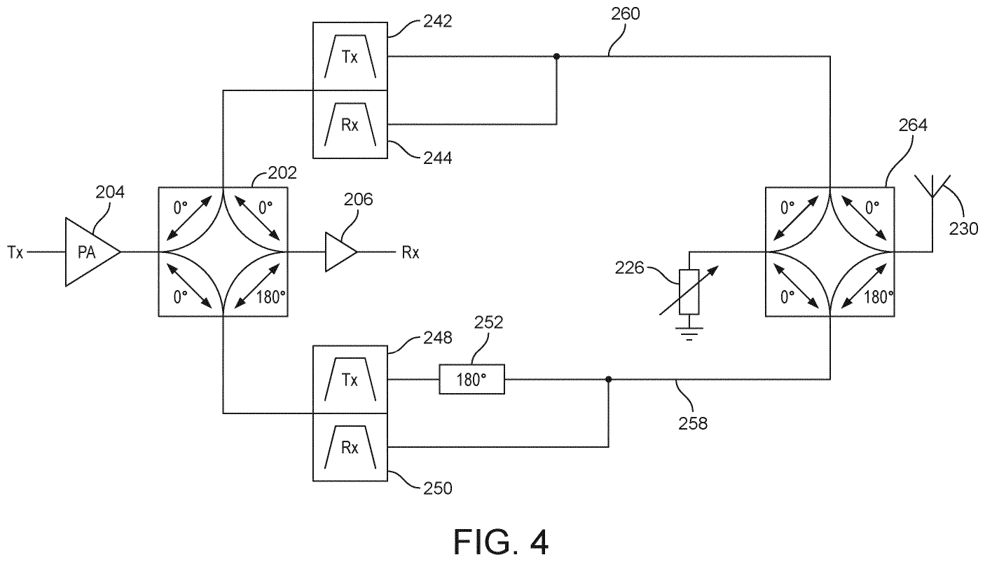

With reference to FIG. 4, an alternative implementation of the improved electrical balanced duplexer of FIG. 2(a) is shown, with a different connection of the receive paths. Where elements and connection points of FIG. 4 correspond to those of FIG. 2(a), like reference numerals are used. It should also be noted that the arrangement of FIG. 4 may be adapted to introduce the variable control aspects of FIG. 3, in the same way that the arrangement of FIG. 2(a) may be adapted.

It can be seen that the difference between the exemplary implementation of FIG. 4 and exemplary implementation of FIG. 2(a), is the connection between the receive filters 244 and 250, and the second hybrid junction 264. As shown in FIG. 4, the receive filter 244 is connected between the port 218 of the first hybrid junction 220, and the port 266 of the second hybrid junction 264. The receive filter 250 is connected between the port 224 of the first hybrid junction and the port 270 of the second hybrid junction. Thus the receive filter is connected between lines 256 and 260, and the receive filter is connected between lines 254 and 258.

In another embodiment, filters 242 and 244 of FIGS. 2(a) and 4 could be omitted or otherwise replaced with an impedance matching network. This would impact on the rejection of unwanted out-of-band signals which the filters provide. Transmit-to-receive isolation may still be achieved by ensuring the impedances presented to the hybrid junction are substantively equal over the frequency band or bands of interest, noting this may be achieved without including two pairs of filter in the system.

At least one filter is required in order to selectively apply a phase shift at either the transmit or receive frequency. Thus for example, referring to FIG. 2(a), the filter 248 may be required, but the filters 242, 244, 250 may be replaced by impedance matching networks.

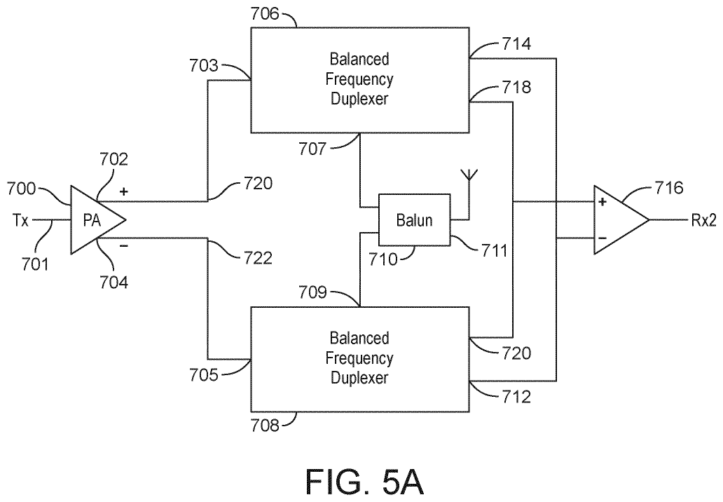

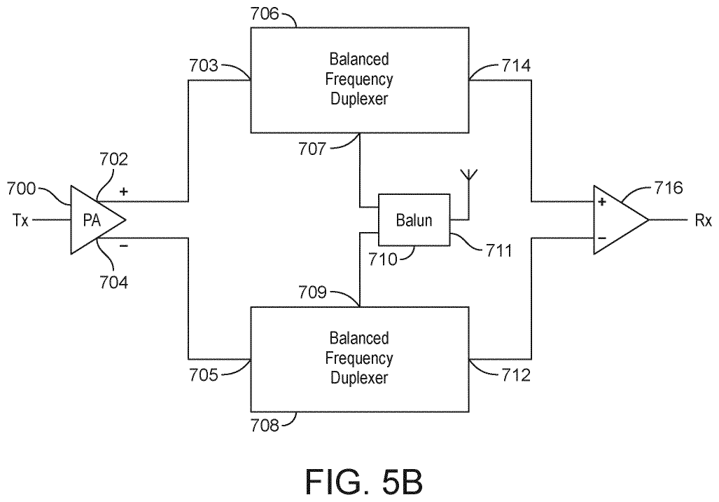

A further example implementation of a duplexer utilising the improved electrical balance duplexer is shown in FIG. 5. FIG. 5 depicts a fully differential implementation.

A differential power amplifier 700 receives a transmit signal Tx on line 701. The differential power amplifier 700 drives a differential output signal on lines 720 and 722 from a differential output comprising terminals 702 and 704 respectively. The terminal 702 is connected to the transmit input 703 of a first improved electrical balance duplexer 706 via line 720. The terminal 704 is connected to the transmit input terminal 703 of a second improved electrical balance duplexer 708 via line 722. In the example embodiment in FIG. 5 the first and second balanced frequency duplexers are connected at their antenna output ports 707 and 709 via the balun 710, which feeds a single ended antenna 711. Alternatively, in other embodiments, a differential antenna may be used. The receiver output of the improved electrical balance duplexers 706 and 708, denoted by reference numerals 714 and 712 respectively, are connected to a differential low noise amplifier 716 which acts as the input to the receiver. The received signal Rx is generated on line 730 at the output of the low noise amplifier 716.

FIG. 5 provides a basic example of how the balanced frequency duplexer concept can be extended to a fully differential implementation.

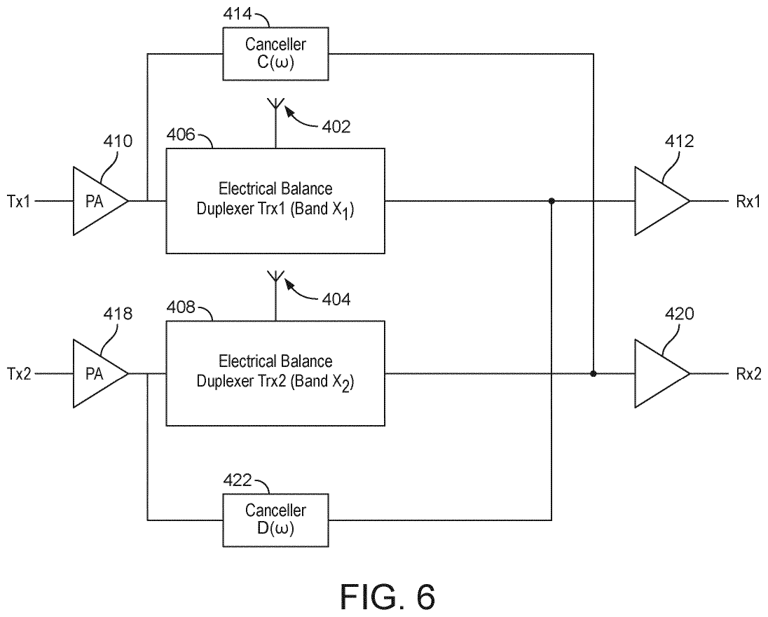

With reference to FIG. 6, there is illustrated an example implementation of a system with multiple antennas, in this example implementation in the system with two antennas, utilising the improved electrical balance duplexer as described above.

As shown in FIG. 6, the system includes a first antenna 402, and a second antenna 404. The first antenna 402 is associated with a first improved electrical balance duplexer 406, and the second antenna is associated with a second improved electrical balance duplexer 408. In certain embodiments, the first and second improved electrical balance duplexers 406 and 408 could, for example, be of the type described above and shown in any one of FIG. 2(a), 2(b), and/or FIG. 4.

The first electrical balance duplexer 406 is associated with a power amplifier 410, and low noise amplifier 412, and an optional canceller 414.

The second electrical balance duplexer 408 is associated with a power amplifier 418, a low noise amplifier 420, and an optional canceller 422.

The power amplifier 410 receives a transmit signal Tx1 and delivers an output to the electrical balance duplexer 406. The electric balanced duplexer 406 receives a signal from the antenna 402 and delivers this to the low noise amplifier 412, which outputs a received signal Rx1.

The power amplifier 418 receives a transmit signal Tx2 and delivers an output to the electric balanced duplexer 408. The electrical balance duplexer 408 receives a signal from the antenna 404 and delivers this received signal to the low noise amplifier 420, which delivers a received signal Rx2.

Each of the cancellers 414 and 422 provide cancellation between the signals Rx1 and Tx2, and Rx2 and Tx1, respectively. The canceller 414 may be provided because the signal Rx2 may comprise unwanted signal components related to Tx1 in addition to the wanted signal components received by the antenna 404. Similarly, the canceller 422 may be provided because the signal Rx1 may comprise unwanted signal components related to Tx2 in addition to the wanted signal components received by the antenna 402. This unwanted signal coupling may, for example, result from electromagnetic coupling between the two antennas 402 and 404.

An example of the use of an arrangement such as shown in FIG. 6 may be in a multiple-in, multiple-out (MIMO) implementation.

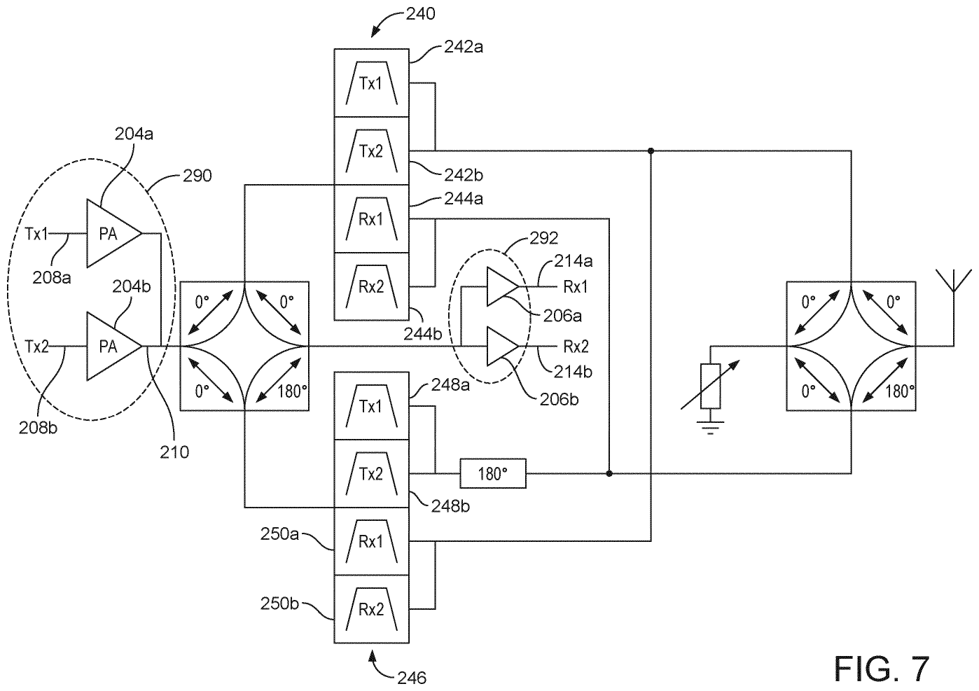

With reference to FIG. 7, there is illustrated an example implementation of a quadplexer, utilising the improved electrical balance duplexer as described above.

It will be apparent from FIG. 7 and the following description that an implementation of an exemplary n-plexer, is apparent from the example implementations of a duplexer as described above.

The exemplary quadplexer of FIG. 7 utilises the same architecture arrangement of the duplexer of FIG. 2(a). Where elements of the arrangement of FIG. 2(a) corresponds to elements of the arrangement of FIG. 7, like reference numerals are used and further discussion is not required.

In the quadplexer of FIG. 7 two transmit signals Tx1 and Tx2 are provided, and two receiver signals Rx1 and Rx2 are received.

The transmits signals Tx1 and Tx2 are provided on respective signal lines 208a and 208b to respective power amplifiers 204a and 204b to the port 226 of the hybrid circuit 202.

The received signal on line 212 is provided as an input to the respective low noise amplifiers 206a and 206b, which provide the respective receive signals Rx1 and Rx2 on lines 214a and 214b.

From the arrangement of FIG. 7 it is evident that a simple extension of the duplexer arrangement such as shown in FIG. 2(a) replaces the power amplifier 204 with n power amplifiers to process n transmit signals, and replaces the low noise amplifier 206 with n low noise amplifiers to process n received signals, to implement an n-plexer. Reference numeral 290 denotes the extension of the power amplifiers, and reference numeral 292 denotes the extension of the low noise amplifiers.

Examples of implementations of hybrid junctions are now discussed. Various implementations exist for hybrid junctions. A hybrid junction may also be referred to as a hybrid transformer, a hybrid coil, a bridge transformer, a magic tee, rat-race coupler, hybrid coupler, or a hybrid circuit.

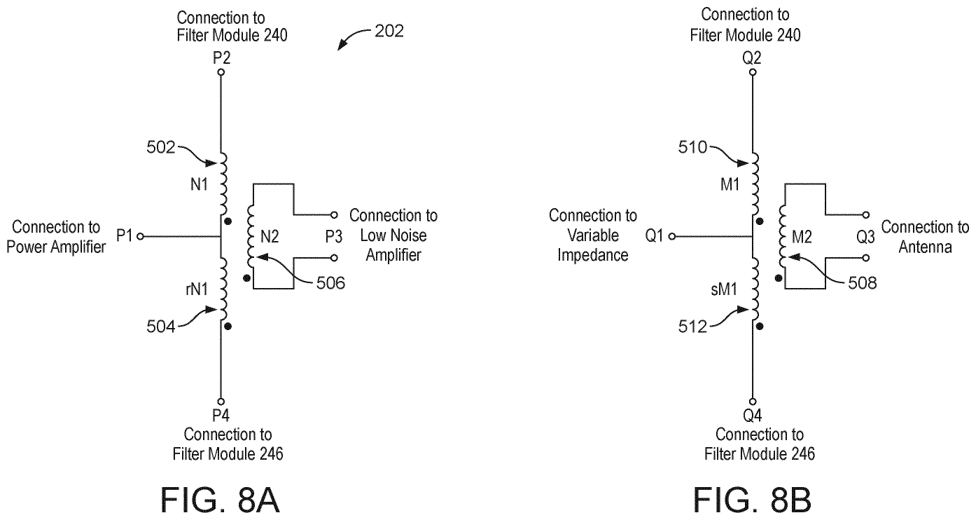

FIGS. 8(a) and 8(b) illustrate example implementations of the hybrid junctions 202 and 264 of FIG. 2(a) or FIG. 4.

The implementation of the hybrid junction 202 of the example shown in FIG. 8(a) may be a transformer comprising primary windings 502 and 504, and a secondary winding 506. The primary winding 502 comprises N₁ turns, and the primary winding 504 comprises rN₁ turns (a multiple of the turns of the winding 502). The secondary winding 506 comprises N₂ turns. One terminal of the primary winding 502 is connected to a port P₂, and one terminal of the primary winding 504 is connected to a port P₄. The other terminals of the primary windings 502 and 504 are connected together at a port P₁. The secondary winding 506 is connected to a port P₃.

In an exemplary implementation of the hybrid junction 202 as shown in FIG. 8(a), the transmit current, supplied by the power amplifier, enters the hybrid junction at the centre tap of the primary winding. The centre tap of the primary winding is denoted by port P₁. This transmit current is split between two paths flowing in opposite directions, with one component flowing to port P2 through winding 502, and one component flowing to port P4 through winding 504. The relative magnitude of these currents is determined by a transformer tapping ratio, denoted r, and by the values of the impedances connected at ports P2 and P4. As discussed above one or more of the impedance connected to the hybrid junction is preferably a tuneable impedance, which is adjusted such that these two currents flowing in the windings 502 and 504 create equal but opposite magnetic fluxes that can cancel, and therefore zero current is induced in the secondary winding (506) of the transformer arrangement, and the receiver is isolated from the transmitter.

Conversely, currents that flow in the same direction throughout the primary winding, for example, if a differential signal is applied across the ports p2 and p4, will result in this signal being be coupled to P3, but not to p1.

The implementation of the hybrid junction 264 of the example shown in FIG. 8(b) may be a transformer comprising primary windings 510 and 512, and a secondary winding 508. The primary winding 512 comprises M₁ turns, and the primary winding 512 comprises rM₁ turns (a multiple of the turns of the winding 510). The secondary winding 508 comprises M₂ turns. One terminal of the primary winding 510 is connected to a port Q₂, and one terminal of the primary winding 512 is connected to a port Q₄. The other terminals of the primary windings 510 and 512 are connected together at a port Q₁. The secondary winding 508 is connected to a port Q₃.

FIG. 8(a) is labelled with one possible set of connections to the transmitter, receiver, and filter modules, which could, for example, enable a transformer to be used in as an implementation of the hybrid junction 202 in FIG. 2(a) 9 or FIG. 2(b)) or FIG. 4. Other mappings of connections are also possible.

Likewise, FIG. 8(b) provides an example of how a transformer could be used to implement the hybrid junction 264 of FIG. 2(a) 9 or FIG. 2(b)) or FIG. 4. Likewise, the labels showing connections to the antenna, variable impedance, and filter modules are exemplary, and other mappings of connections are also possible, for example in different embodiments that use different phase in the signal junction (e.g. FIG. 2(a) versus FIG. 2(b)).

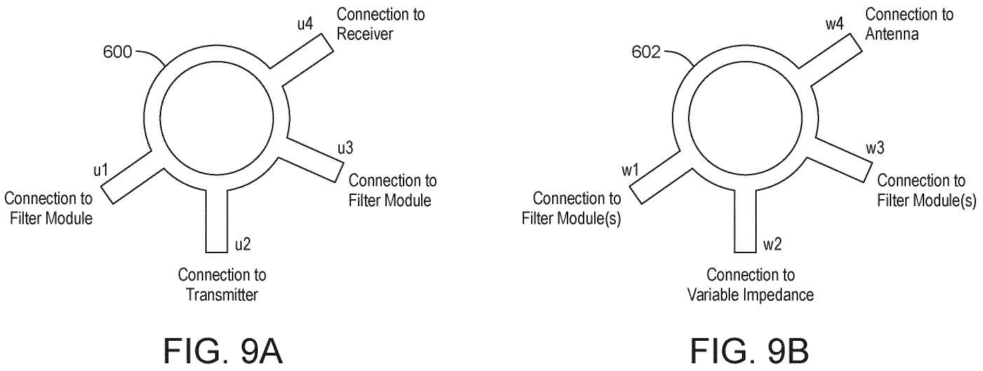

FIGS. 9(a) and 9(b) illustrate further example implementations of the hybrid junctions 202 and 264 of FIG. 2(a) or FIG. 4. In this example implementation the hybrid junctions 202 and 204 are each implemented using a rat-race coupler (also known as hybrid rings).

FIGS. 9(a) and 9(b) show examples of a rat-race coupler, implemented using microstrip technology. The operation of the rat-race coupler relies on the geometry of the microstrip structure.

In FIG. 9(a) the ports of the rat-race coupler 600 are denoted u1, u2, u3, u4 and are separated around the ring structure 600 at selected distances related to fractions of a wavelength at the operating frequency. U1 and u2 are separated by a quarter wavelength, meaning signals experience a −90° phase shift between these ports when travelling directly from port u1 to u2. When travelling indirectly from port u1 to u2, via the longer path around the ring structure (in the other direction) signals experiences a −450° phase shift, therefore arriving at port u2 in phase with the signal which has experienced a −90° phase shift. The same is true of coupling between ports u2 and u3, and between ports u3 and u4. Signals entering port u2 are not coupled to port u4, as the signal travelling anti-clockwise from u2 to u4 experiences a 180° phase shift, whilst the signal travelling clockwise experiences a 360° phase shift, thereby isolating these ports. The same is true of the relationship between ports u3 and u1, isolating these ports also. The rat-race coupler 600 may be used as the hybrid junction 202 in the example embodiment in FIG. 2(a). FIG. 9(a) is also labelled with one possible set of connections to the transmitter, receiver, and filter modules, which could, for example, enable the rat-race coupler 600 to be used in as an implementation of the hybrid junction 202 in FIG. 2(a) or FIG. 4. Other mappings of connections are also possible. Likewise, FIG. 9(b) provides an example of how the rat-race coupler 602 could be used to implement the hybrid junction 264 of FIG. 2(a) or FIG. 4. Likewise, the labels showing connections to the antenna, variable impedance, and filter modules are exemplary, and other mappings of connections are also possible.

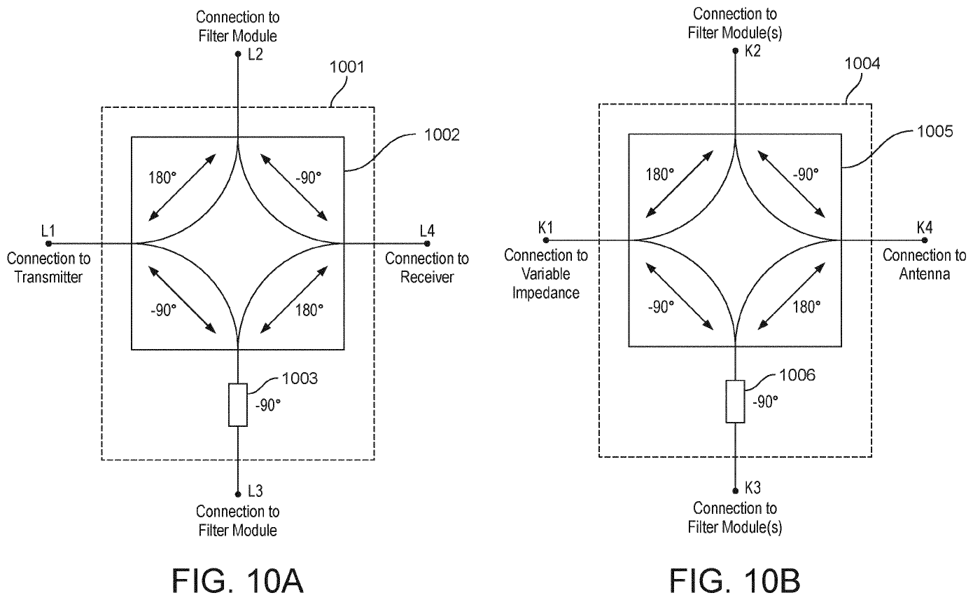

FIGS. 10(a) and 10(b) illustrate a further implementation of a signal junction. In this example, a quadrature hybrid coupler is used. A signal junction 1001 comprises a quadrature hybrid coupler 1002 with a −90° phase shifter 1003 connected in series at one of its ports. A quadrature hybrid coupler is well known to split a signal at the input of any one of its ports into a pair of output signals at adjacent ports with a 90° (quadrature) phase difference between those output signals. The inclusion of the phase shifter 1003 has the effect that the signal junction 1001 has relative phase relationships between ports which are the same as those of a 180° hybrid junction. The phase shifter 1003 could be connected at any one of the ports of the quadrature hybrid coupler 1002.

A signal entering a port L1 is split between ports L2 and L3. The resulting signal output at port L2 is phase shifted by 180° due to the quadrature hybrid coupler 1002. The resulting signal output at port L3 is also shifted by 180° due to the combined affect of the quadrature coupler 1002, and the −90° phase shifter 1003. Thus a signal entering port L3 appears in common mode at ports L2 and L3.

Likewise, it can be seen from the phase relationships in this signal junction that a signal which appears in differential mode across the ports L2 and L3 will be output at port L4, and not port L1.

FIG. 10(a) is also labelled with one possible set of connections to the transmitter, receiver, and filter modules, which could, for example, enable the signal junction 1001 to be used in as an implementation of the hybrid junction 202 in previous figures. Other mappings of connections are also possible.

Likewise, FIG. 10(b) provides an example of how a signal junction 1004 using a hybrid coupler 1005 and −90° phase shifter 1006 could be used to implement the hybrid junction 264 of FIG. 2(a) or FIG. 4. Likewise, the labels showing connections to the antenna, variable impedance, and filter modules are exemplary, and other mappings of connections are also possible.

Where the improved electrical balance frequency duplexers are implemented as shown in FIG. 2(a) and use hybrid transformers of the type shown in FIGS. 8a to implement the hybrid junction 202, it may be possible to connect the receiver windings 506 of the balanced frequency duplexers 706 and 708 in parallel across the differential inputs of the low noise amplifier 716.

The implementation of variable filters and/or a variable antenna balancing impedance, and the use of a microprocessor to control such as shown in FIG. 3, may apply to any implementation of an improved electrical balance circuit, including any one of the arrangements shown in FIG. 2(a), 2(b) or 4.

An improved electrical balance circuit may use any one of the hybrid junction/signal junction arrangements as shown in any one of FIGS. 8(a), 8(b), 9(a), 9(b), 10(a) and 10(b), and may use other implementations.

An n-plexer, MIMO, or differential circuit arrangement of an n-plexer or MIMO may use any electrical balance circuit as described, and/or any hybrid/signal junction as described.

Various examples and embodiments refer to hybrid junctions, particularly a first and second hybrid junction. In general, the first and second hybrid junctions are first and second signal junctions. THE term hybrid junction and signal junction are interchangeable wherever used herein. The first signal junction is preferably a four-port signal junction, such as the illustrated hybrid junction. The second signal junction may be a three-port signal junction, such as a balun, and is preferably a four-port hybrid junctions, such as the illustrated hybrid junction.

In general the first signal junction generates a pair of differential mode or common mode transmit signals output from two ports thereof. The differential mode or common mode transmit signals are connected to two ports of the second signal junction, such that they combine in-phase at the antenna port of the second signal junction.

In general the second signal junction generates a pair of differential mode or common mode receive signals output from two ports thereof. The differential mode or common mode receive signals are connected to two ports of the first signal junction, such that they combine in phase at the receive port of the first signal junction.

One or more filters and one or more phase shifters is preferably included in one or more of the pair of transmit paths, or one or more of the pair of receive paths, such that the transmit signals combine in phase at the antenna port of the second signal junction, and receive signals combine in phase at the receive port of the first signal junction.

Various examples and embodiments have been set out as circuits or apparatus. The invention is not limited to circuits or apparatus. The invention may be embodied by methods or processes. Methods or processes may be implemented, at least in part, utilising computer processing techniques. A computer program code may be provided which, when executed on a processor, such as the processor illustrated in examples above, may perform any method or process, at least in part. A computer program product may be provided on which such computer program code is stored.

Various examples and embodiments have been set out to illustrate the invention. Aspects of examples and embodiments may be combined. For example, exemplary implementations of an n-plexer, a MIMO and differential arrangement are described. Each of these may be combined.

The invention has been described by way of reference to various embodiments and implementations. The invention is not limited to the specifics of any example. The scope of protection afforded by the invention is defined by the appended claims.

1. A circuit for transmitting a transmit signal at a transmit frequency and receiving a receive signal at a receiver frequency, for use with a common antenna, comprising:
a first signal junction having a transmit port for receiving the transmit signal, a receive port for outputting the receive signal, a third port and a fourth port, wherein the third and fourth port are for outputting a pair of common mode or differential mode transmit signals which are split from the transmit signal at the transmit port, and for receiving a pair of common mode or differential mode receive signals which are combined and provided to the receive port;
a second signal junction having an antenna port for connection to an antenna, a second port and a third port, wherein the second and third port are for outputting the pair of common mode or differential mode receive signals which are split from the signal received at the antenna port, and for receiving the pair of common mode or differential mode transmit signals which are combined and provided to the antenna port;
a phase inverter connected in a path of one of the pair of differential or common mode transmit or receive signals, wherein the pair of receive signals received at the receiver port are in-phase and the pair of transmit signals received at the antenna port are in-phase.

2-76. (canceled)
